(19) United States
(12) Patent Application Publication
(10) Pub. No.: US 2025/0169328 A1
(43) Pub. Date: May 22, 2025

(54) DISPLAY DEVICE

(71) Applicant: LG Display Co., Ltd., Seoul (KR)

(72) Inventors: Taehyeon KIM, Paju-si (KR); MyungHo BAN, Paju-si (KR); KyungMin KIM, Paju-si (KR); Sejong SEONG, Paju-si (KR)

(73) Assignee: LG Display Co., Ltd., Seoul (KR)

(21) Appl. No.: 18/933,799

(22) Filed: Oct. 31, 2024

(30) Foreign Application Priority Data
Nov. 20, 2023 (KR) 10-2023-0160509

(51) Int. Cl. H10K 59/80; H10K 59/123; H10K 102/00; H10K 102/10

(52) U.S. Cl. CPC H10K 59/80515; H10K 59/123; H10K 59/80518; H10K 59/80521; H10K 2102/103; H10K 2102/351

(57) ABSTRACT

Discussed is a display device with improved light extraction efficiency. In the display device according to an example, an overcoat layer is disposed over a substrate. A first anode is disposed over the overcoat layer and includes at least one anode open area. A second anode is disposed over the same layer as the first anode. A portion of the second anode is disposed in the anode open area. A light-emitting layer is disposed over the first anode and the second anode. A cathode is disposed over the light-emitting layer.

### CROSS-REFERENCE TO RELATED APPLICATION

This application claims priority to Korean Patent Application No. 10-2023-0160509, filed in the Republic of Korea on Nov. 20, 2023, the entire contents of which is hereby expressly incorporated by reference into the present application.

### BACKGROUND

### Field

Embodiments of the present disclosure relate to a display device with improved light extraction efficiency.

### Discussion of the Related Art

A light-emitting display device is supplied with light for displaying images by a light-emitting layer that emits light by itself.

Light emitted from the light-emitting layer of the light-emitting display device can pass through various components of the light-emitting display device to exit the light-emitting display device.

However, since the light emitted from the light-emitting layer can spread in various directions, the emitted light can also travel into the light-emitting display device. At this time, a portion of the light traveling into the light-emitting display device can be trapped inside the light-emitting display device instead of exiting the light-emitting display device, and the light trapped inside the light-emitting display device can undesirably lower the light extraction efficiency of the display device.

### SUMMARY OF THE DISCLOSURE

Embodiments of the present disclosure can provide a display device having a structure able to improve light extraction efficiency.

Embodiments of the present disclosure can provide a display device including: an overcoat layer over a substrate; a first anode disposed over the overcoat layer and including at least one anode open area; a second anode disposed over the same layer as the first anode, with a portion thereof being disposed in the anode open area; a light-emitting layer disposed over the first anode and the second anode; and a cathode disposed over the light-emitting layer.

Embodiments of the present disclosure can provide a display device including: an overcoat layer over a substrate; a plurality of first anodes disposed over the overcoat layer to be spaced apart from each other; a plurality of second anodes disposed over the same layer as the first anodes such that the second anodes are spaced apart from each other, the second anodes alternating with the first anodes while filling between the first anodes; a light-emitting layer disposed over the first anodes and the second anodes; and a cathode disposed over the light-emitting layer.

Embodiments of the present disclosure can provide a display device including: a transistor on a substrate; an overcoat layer disposed over the transistor and having an open area; a first anode disposed over the overcoat layer and including at least one anode open area; a second anode disposed over the same layer as the first anode, with at least a portion thereof being disposed in the anode open area; and a second anode connector horizontally extending from a peripheral portion of the first anode and disposed to cover the open area.

According to embodiments of the present disclosure, the display device can have a structure able to improve light extraction efficiency.

According to embodiments of the present disclosure, the display device can serve as a low power display device by improving light extraction efficiency.

It is to be understood that both the foregoing general description and the following detailed description are exemplary and explanatory and are intended to provide further explanation of the inventive concepts as claimed.

### BRIEF DESCRIPTION OF THE DRAWINGS

The above and other objects, features, and advantages of the present disclosure will be more clearly understood from the following detailed description, taken in conjunction with the accompanying drawings, in which:

FIG. 1 illustrates an example structure of a display device according to embodiments of the present disclosure and a circuit structure included each of subpixels in the display device;

FIG. 2 illustrates a cross-sectional structure of a general display device;

FIG. 3 illustrates an example planar structure of the display device according to embodiments of the present disclosure;

FIG. 4 illustrates an example cross-sectional structure of part along line A-A′ in FIG. 3;

FIG. 5 illustrates the principle by which the light extraction efficiency of the display device according to embodiments of the present disclosure is improved;

FIG. 6 illustrates an optical simulation image in a cross-sectional structure of the display device according to embodiments of the present disclosure;

FIG. 7 illustrates another example planar structure of the display device according to embodiments of the present disclosure;

FIGS. 8A and 8B illustrate an example cross-sectional structure of part along line B-B′ in FIG. 7;

FIGS. 9A to 9C illustrate various example planar structures of the display device according to embodiments of the present disclosure;

FIG. 10 illustrates another example planar structure of the display device according to embodiments of the present disclosure;

FIGS. 11A and 11B illustrate example cross-sectional structures of part along line C-C′ in FIG. 10.

FIG. 12 is an enlarged view of part D in FIG. 11A;

FIG. 13 illustrates an example planar structure including a circuit connector in the display device according to embodiments of the present disclosure;

FIG. 14 illustrates an example cross-sectional structure of part along line E-E′ in FIG. 13; and

FIG. 15 illustrates another example planar structure including a circuit connector in the display device according to embodiments of the present disclosure.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description can make the subject matter in some embodiments of the present disclosure rather unclear. The terms such as “including”, “having”, “containing”, “constituting” “made up of”, and “formed of” used herein are generally intended to allow other components to be added unless the terms are used with the term “only”. As used herein, singular forms are intended to include plural forms unless the context clearly indicates otherwise.

Names of the respective elements used in the following explanations may be selected only for convenience of writing the specification and may be thus different from those used in actual products.

Advantages and features of the present disclosure, and implementation methods thereof will be clarified through following example embodiments described with reference to the accompanying drawings. The present disclosure may, however, be embodied in different forms and should not be construed as limited to example embodiments set forth herein. Rather, these example embodiments may be provided so that this disclosure may be sufficiently thorough and complete to assist those skilled in the art to fully understand the scope of the present disclosure. Further, the present disclosure is only defined by scopes of claims.

The shapes (e.g., sizes, lengths, widths, heights, thicknesses, locations, radii, diameters, and areas), ratios, angles, numbers of elements, and the like, which are illustrated in the drawings to describe various example embodiments of the present disclosure are merely given by way of example. Therefore, the present disclosure is not limited to the illustrations in the drawings. Any implementation described herein as an “example” is not necessarily to be construed as preferred or advantageous over other implementations.

Terms, such as “first”, “second”, “A”, “B”, “(A)”, or “(B)” can be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other. The terms, such as “below,” “lower,” “above,” “upper” and the like, may be used herein to describe a relationship between element(s) as illustrated in the drawings. It will be understood that the terms are spatially relative and based on the orientation depicted in the drawings.

In describing a positional relationship where the positional relationship between two parts is described, for example, using “on,” “over,” “under,” “above,” “below,” “beneath,” “near,” “close to,” “adjacent to,” “beside,” “next to,” or the like, one or more other parts can be located between the two parts unless a more limiting term, such as “immediate(ly),” “direct(ly),” or “close(ly),” is used.

When time relative terms, such as “after”, “subsequent to”, “next”, “before”, and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may”.

Hereinafter, a variety of exemplary embodiments of the present disclosure will be described in detail with reference to the accompanying drawings. All the components of each display device or apparatus according to all embodiments of the present disclosure are operatively coupled and configured.

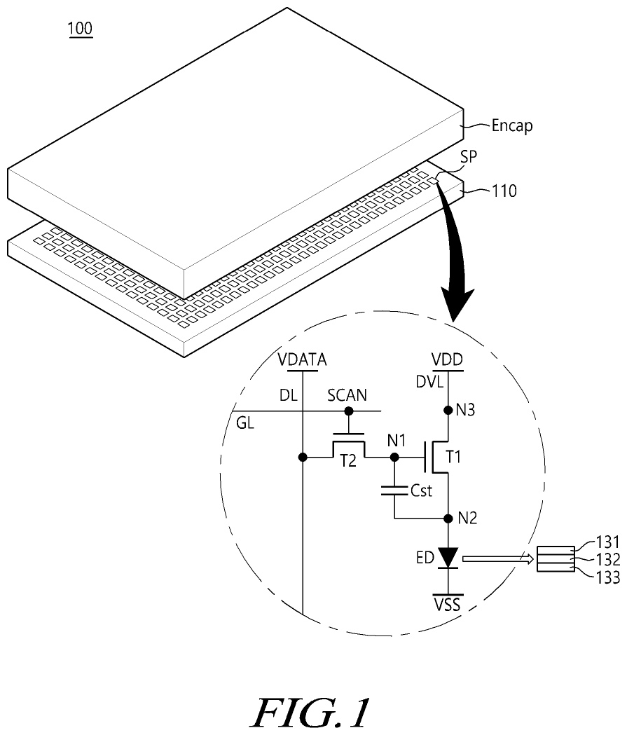

FIG. 1 illustrates an example structure of a display device according to embodiments of the present disclosure and a circuit structure included in each of subpixels in the display device.

Referring to FIG. 1, a plurality of subpixels SP can be arranged in a display area of a display panel 110 of a display device 100.

Each of the subpixels SP can include a light-emitting element ED and a subpixel circuit configured to drive the light-emitting element ED.

The subpixel circuit can include a driving transistor T1 for driving the light-emitting element ED, a scanning transistor T2 for transferring a data voltage VDATA to a first node N1 of the driving transistor T1, a storage capacitor Cst for maintaining a constant voltage during a certain period (e.g., a single frame), and the like.

The driving transistor T1 can include a first node N1 to which a data voltage can be applied, a second node N2 electrically connected to the light-emitting element ED, and a third node N3 to which a driving voltage VDD is applied from a driving voltage line DVL. In the driving transistor T1, the first node N1 can be a gate node, the second node N2 can be a source node or a drain node, and the third node N3 can be a drain node or a source node. In the following, for the sake of brevity, a case in which the first node N1 can be a gate node, the second node N2 can be a source node, and the third node N3 can be a drain node in the driving transistor T1 is taken as an example.

The light-emitting element ED can include an anode 131, a light-emitting layer 132, and a cathode 133. The anode 131 can be a pixel electrode disposed in each of the subpixels SP, and can be electrically connected to the second node N2 of the driving transistor T1 of each of the subpixels SP. The cathode 133 can be a common electrode disposed in common in the subpixels SP, or a common electrode disposed in common in some of the subpixels SP, and a base voltage VSS can be applied to the cathode 133. Embodiments are not limited thereto. As an example, the cathode 133 can be also separately disposed in each of the subpixels SP.

Alternatively, the anode 131 can be a common electrode and the cathode 133 can be a pixel electrode. In the following, for the sake of brevity, it is assumed that the anode 131 is a pixel electrode and the cathode 133 is a common electrode.

The light-emitting element ED can have a predetermined light-emitting area, and the number of light-emitting areas can be one or more, as will be described later.

The light-emitting element ED can be an organic light-emitting diode (OLED), an inorganic light-emitting diode, a quantum dot light-emitting device, a Mini-LED, a Micro-LED, or the like. When the light-emitting element ED is an OLED, the light-emitting layer 132 in the light-emitting element ED can include an organic light-emitting layer (EML) containing an organic material.

The scanning transistor T2 can be on-off controlled by a scanning signal SCAN, which is a gate signal applied through a gate line GL, and can be electrically connected to the first node N1 of the driving transistor T1 and to a data line DL.

The storage capacitor Cst can be electrically connected to the first node N1 and the second node N2 of the driving transistor T1.

The subpixel circuit can have a 2T1C structure including two transistors DT and ST and one capacitor Cst. In some cases, the subpixel circuit can further include one or more transistors or one or more capacitors.

The storage capacitor Cst can be an external capacitor intentionally designed to be outside of the driving transistor T1, rather than being a parasitic capacitor (e.g., Cgs or Cgd), which is an internal capacitor present between the first node N1 and the second node N2 of the driving transistor T1. Each of the driving transistor T1 and the scanning transistor T2 can be an n-type transistor or a p-type transistor.

Since the circuit elements (in particular, the light-emitting element ED implemented as an OLED including an organic material) in each of the subpixels SP are susceptible to external moisture, oxygen, or the like, an encapsulation layer Encap can be disposed over the display panel 110 to reduce or prevent external moisture or oxygen from penetrating the circuit elements (in particular, the light-emitting element ED). The encapsulation layer Encap can be configured to cover the light-emitting element ED.

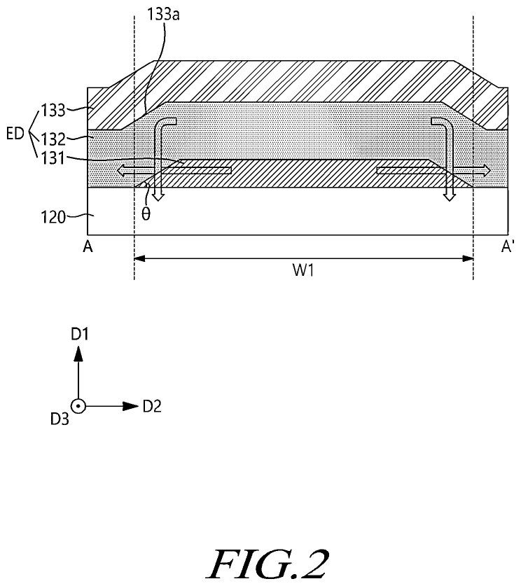

FIG. 2 illustrates a cross-sectional structure of a general display device.

Referring to FIG. 2, the display panel 110 of the display device 100 can include a substrate (not shown) on which a plurality of subpixels SP each having a light-emitting area and a non-light-emitting area are disposed.

An overcoat layer 120 can be disposed over the substrate.

Various buffer layers, various transistors including the driving transistor T1 for driving the light-emitting element ED, and a plurality of insulating layers can be disposed between the substrate and the overcoat layer 120.

The buffer layer can serve to improve adhesion between a layer formed over the buffer layer and the substrate and to delay the diffusion of moisture or oxygen that has penetrated the substrate.

The driving transistor T1 for driving the light-emitting element ED and transistors for transmitting various signals and voltages can be disposed on the buffer layer.

A plurality of insulating layers for electrical isolation can be disposed over or under the various transistors. Some of the insulating layers can be provided with holes for electrical connection between the source or drain electrode of the driving transistor T1 and the light-emitting element ED.

The overcoat layer 120 can be disposed over the insulating layers.

The overcoat layer 120 can protect the underlying transistors and can reduce or flatten step portions caused by various patterns.

The overcoat layer 120 can be formed of, but is not limited to, at least one of organic insulating materials such as a benzocyclobutene (BCB), an acrylic resin, an epoxy resin, a phenolic resin, a polyamide resin, or a polyimide resin.

An anode 131 can be disposed over the overcoat layer 120.

When the display device 100 has a bottom emission structure, the anode 131 can be implemented using a transparent conductive material transmitting light. For example, the anode 131 can be formed of, but is not limited to, at least one of indium tin oxide (ITO) or indium zinc oxide (IZO). Embodiments are not limited thereto. As an example, the display device 100 can have a top emission structure. As an example, the anode 131 can be implemented using any conductive material transmitting or not transmitting light. As an example, the anode 131 can be implemented using a transparent conductive material or an opaque conductive material as a reflective electrode reflecting light. For example, the anode 131 can be formed of at least one of silver (Ag), aluminum (Al), gold (Au), molybdenum (Mo), tungsten (W), chromium (Cr), or alloys thereof, without being limited thereto.

Particularly, FIG. 2 illustrates a structure in which the anode 131 is disposed in a light-emitting area of a subpixel SP. The light-emitting area can be defined as an area in which the anode 131, the light-emitting layer 132, and the cathode 133 are arranged to overlap each other.

The anode 131 can also be disposed in an area other than the light-emitting area of the subpixel SP. For example, the anode 131 can be disposed to further extend in a direction parallel to a direction D3 for electrical connection to the driving transistor T1 disposed under the overcoat layer 120, without being limited thereto.

The anode 131 can have a width of W1 in a direction D2 in the light-emitting area of the subpixel SP.

As an example, the anode 131 can be configured such that a peripheral portion thereof is inclined. Since the peripheral portion of the anode 131 is inclined, the height of the peripheral portion of the anode 131 in a direction D1 can be lower than the height of the central portion of the anode 131 in the direction D1.

In addition, the inclination of the peripheral portion of the anode 131 can have an angle θ in the range of 0° to 90°. As the angle of the peripheral portion of the anode 131 is in the range of 0° to 90°, each of the light-emitting layer 132 and the cathode 133 described later can form an inclination angle in the peripheral portion.

The light-emitting layer 132 can be disposed over the anode 131 and a portion of the overcoat layer 120.

The light-emitting layer 132 can include an organic light-emitting layer (EML), which can include one of a red organic light-emitting layer (REML), a green organic light-emitting layer (GEML), or a blue organic light-emitting layer (BEML). Embodiments are not limited thereto. As an example, the organic light-emitting layer can further include a white organic light-emitting layer. As an example, the organic light-emitting layer can alternatively or additionally include an organic light-emitting layer of other colors, such as cyan, magenta, yellow, etc.

In addition to the organic light-emitting layer (EML), the light-emitting layer 132 can further include, but is not limited to, a hole injection layer, a hole transport layer, an electron transport layer, and an electron injection layer. As an example, at least one or all of the hole transport layer, the electron transport layer, and the electron injection layer can be omitted, depending on the design.

The light-emitting layer 132 can have a sloped surface, the angle of which is the same angle as the inclination of a peripheral portion of the anode 131, in an area overlapping a peripheral area of the anode 131.

For example, the height of the top surface of the light-emitting layer 132 in areas overlapping the anode 131 can be higher than the height of the top surface of the light-emitting layer 132 in areas not overlapping the anode 131.

The cathode 133 can be disposed over the light-emitting layer 132.

When the display device 100 has a bottom emission structure, the cathode 133 can be implemented using an opaque conductive material as a reflective electrode reflecting light. For example, the cathode 133 can be formed of at least one of silver (Ag), aluminum (Al), gold (Au), molybdenum (Mo), tungsten (W), chromium (Cr), or alloys thereof. Embodiments are not limited thereto. As an example, the cathode 133 can be also implemented using a transparent conductive material transmitting light, such as an indium tin oxide (ITO) or indium zinc oxide (IZO), without being limited thereto.

The cathode 133 can have a sloped surface, the angle of which is the same as the inclination of a peripheral portion of the anode 131, in the area overlapping the peripheral area of the anode 131.

For example, the height of the top surface of the cathode 133 in areas overlapping anode 131 can be higher than the height of the top surface of cathode 133 in areas not overlapping the anode 131.

In addition, the cathode 133 can include a cathode sloped portion 133a in the area overlapping the peripheral area of the anode 131.

The angle of the cathode sloped portion 133a can be the same as the inclination of the peripheral portion of the anode 131.

Referring to FIG. 2, the encapsulation layer Encap can be disposed over the cathode 133. The encapsulation layer Encap can protect the light-emitting element ED from external moisture, oxygen, or foreign matter. For example, oxygen and moisture can be reduced or prevented from penetrating the light-emitting element ED to reduce or prevent oxidation of the light-emitting material and the electrode material.

As an example, the encapsulation layer Encap can include a first encapsulation layer, a second encapsulation layer, and a third encapsulation layer to reduce or prevent the penetration of moisture or oxygen. The encapsulation layer Encap can have a structure in which the first encapsulation layer, the second encapsulation layer, and the third encapsulation layer are sequentially stacked. Embodiments are not limited thereto. As an example, the encapsulation layer Encap can include one single encapsulation layer, or two encapsulation layers or more than three encapsulation layers.

As shown in FIG. 2, when the display device 100 has a bottom emission structure, a portion of light emitted from the light-emitting layer 132 can be reflected by the cathode sloped portion 133a and travel downwards. As a result, among the emitted light, a portion of light traveling into the display device 100, i.e., light trapped inside by total reflection at an interface of the components inside the display device 100, can be extracted to the outside by the related display device 100.

However, since the cathode sloped portion 133a is disposed only in the area overlapping the peripheral area of the anode 131 and the size of the reflecting area is small, the light extraction efficiency is somewhat reduced. In other words, as shown in FIG. 2, only a portion of the light traveling into the display device 100 is extracted to the outside by the cathode sloped portion 133a, and the remaining portion of the light is not extracted to the outside but remains trapped inside the display device 100 by the total reflection at the interface of the internal components, thereby resulting in a reduction in the light extraction efficiency.

In the following, a display device according to exemplary embodiments of the present disclosure intended to overcome the above-described problem will be described with reference to the drawings.

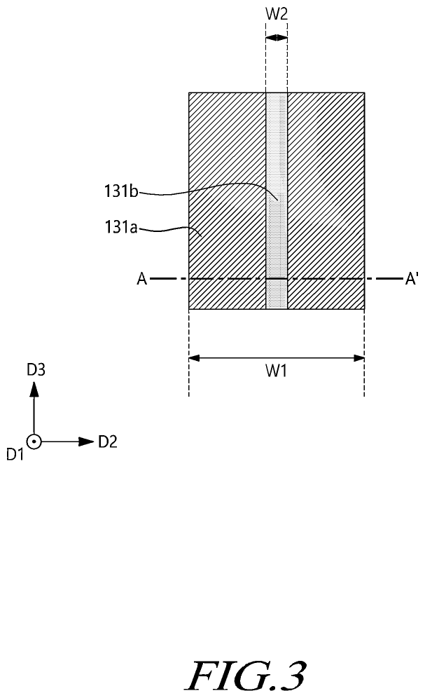

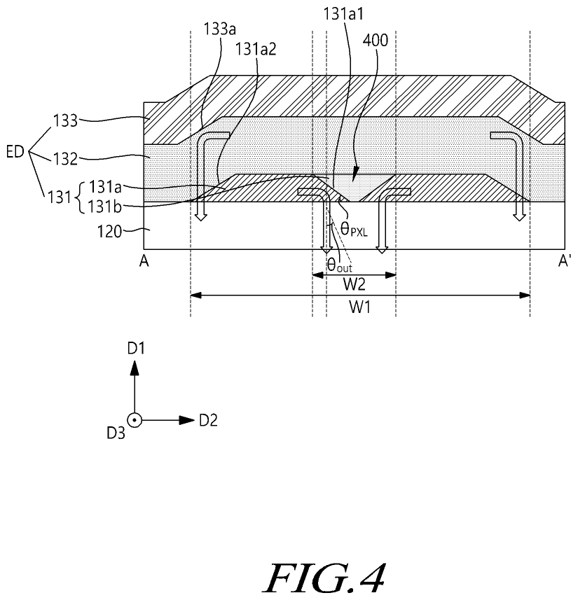

FIG. 3 illustrates an example planar structure of the display device according to embodiments of the present disclosure. FIG. 4 illustrates an example cross-sectional structure of part along line A-A′ in FIG. 3.

In the following, a repeated description of those described above with reference to FIG. 2 will be omitted or briefly given.

Referring to FIGS. 3 and 4, the anode 131 can include a first anode 131a and a second anode 131b.

The first anode 131a can have at least one anode open area 400. The anode open area 400 can have, but is not necessarily limited to, an inverted trapezoidal shape. As an example, the anode open area 400 can have a shape in which a width of the top surface of the anode open area 400 is greater than a width of the bottom surface of the anode open area 400.

When the anode open area 400 has the inverted trapezoidal shape, the width of the top surface of the anode open area 400 can be W2 and the width of the bottom surface of the anode open area 400 can be less than W2. As an example, the anode open area 400 can penetrate the first anode 131a to expose the overcoat layer 120, or the anode open area 400 may not penetrate the first anode 131a, with a portion of the first anode 131a interposed between the anode open area 400 and the overcoat layer 120. Although it is illustrated that the anode open area 400 is disposed in a center portion of the first anode 131a in the second directions, embodiments are not limited thereto. As an example, the anode open area 400 can be disposed at any position in the second directions, or can be dispose at any position in the third direction, without being limited thereto. Although it is illustrated that there is only one anode open area 400 in the first anode 131a, embodiments are not limited thereto. As an example, there could be more than one anode open area 400 in the first anode 131a.

Since the first anode 131a has the anode open area 400, the first anode 131a can have at least one of a first sloped portion 131a1 in an area in which the anode open area 400 is formed and a second sloped portion 131a2 in a peripheral area thereof. As an example, the inclination angle θ_{PXL} of the first sloped portion 131a1 of the first anode 131a can be the same as the inclination angle of the second sloped portion 131a2 of the first anode 131a. Embodiments are not limited thereto. As an example, the inclination angle of the first sloped portion 131a1 of the first anode 131a can be greater than or smaller than the inclination angle of the second sloped portion 131a2 of the first anode 131a. As an example, a length of the first sloped portion 131a1 of the first anode 131a in the second direction can be the same as or different from a length of the second sloped portion 131a2 of the first anode 131a in the second direction.

The inclination angle θ_{PXL} of the first sloped portion 131a1 of the first anode 131a can be a value between 0° and 90°. When the first anode 131a is formed over the overcoat layer 120, as an example, the surface of the overcoat layer 120 can be plasma treated to improve the adhesion between the first anode 131a and the overcoat layer 120, thereby forming the inclination angle of the first sloped portion 131a1 of the first anode 131a to be less than 90°.

The first anode 131a can be implemented using a transparent conductive material transmitting light. For example, the first anode 131a can be formed of, but is not limited to, at least one of indium tin oxide (ITO) or indium zinc oxide (IZO).

In FIG. 4, the first anode 131a is shown as only disposed in the light-emitting area of the subpixel SP, but the first anode 131a can extend further in a direction parallel to the direction D3. As an example, the first anode 131a can extend further in a direction parallel to the direction D3 for electrical connection to the driving transistor T1 disposed under the overcoat layer 120 in addition to the light-emitting area.

The second anode 131b can be disposed to fill the anode open area 400. As an example, the second anode 131b can have the same thickness in the vertical direction as the first anode 131a. For example, the height of the top surface of the second anode 131b can be the same as the height of the top surface of the first anode 131a.

As an example, the second anode 131b can completely fill the anode open area 400. As an example, when the second anode 131b has the same thickness as the first anode 131a, the width of the top surface of the second anode 131b can be W2 and the width of the bottom surface can be less than W2 because the second anode 131b completely fills the anode open area 400. Embodiments are not limited thereto. As an example, there can be a gap between the anode open area 400 and the second anode 131b. As an example, the second anode 131b may not completely fill the anode open area 400. As an example, a top surface of the second anode 131b can be higher than or lower than a top surface of the first anode 131a. As an example, the second anode 131b can be implemented using an opaque conductive material as a reflective electrode reflecting light. For example, the second anode 131b can be formed of at least one of silver (Ag), aluminum (Al), gold (Au), molybdenum (Mo), tungsten (W), chromium (Cr), or alloys thereof.

However, when the opaque second anode 131b is disposed, the amount of light emitted from the light-emitting layer 132 can be partially reduced due to the diffraction of light. Thus, in order to reduce or minimize the diffraction of light, it is desirable for the width of the second anode 131b in the direction D2 (the width W2 of the top surface of the second anode 131b) to have a value greater than the wavelength of the light to be extracted. For example, W2 can be about 700 nm or more, without being limited thereto.

The second anode 131b can be disposed in the light-emitting area in each of the subpixels SP, or in each of at least some of the subpixels SP.

The first anode 131a and the second anode 131b can be electrically connected. Since the first anode 131a and the second anode 131b are electrically connected, each first anode 131a can be electrically connected even in the case that the first anode 131a has the anode open area 400 (e.g., even in the case that the anode open area 400 separates the first anode 131a into two separate parts).

The light-emitting layer 132 can be disposed over the first anode 131a, the second anode 131b, and the overcoat layer 120.

When the first anode 131a and the second anode 131b have the same thickness, for example, when the top surface of the first anode 131a and the top surface of the second anode 131b have the same height, the light-emitting layer 132 can have a flat top surface.

As the light-emitting layer 132 has the flat top surface in the area in which the first anode 131a and the second anode 131b are disposed, current can flow to the light-emitting layer 132 uniformly, thereby reducing or preventing the light characteristics from deteriorating.

However, since the light-emitting layer 132 is formed along step portions of the substructure, the light-emitting layer 132 can have the same inclination angle as the first anode 131a in a peripheral area of the light-emitting layer 132.

For example, in a peripheral area of the first anode 131a or in an area overlapping the area in which the second sloped portion 131a2 of the first anode 131a is disposed, the light-emitting layer 132 can have a sloped surface.

The cathode 133 can be disposed over the light-emitting layer 132.

Like the light-emitting layer 132, the cathode 133 can have the same inclination angle as the first anode 131a in the peripheral area of the light-emitting layer 132.

For example, the cathode 133 can have a flat top surface when the first anode 131a and the second anode 131b have the same thickness, and the cathode 133 can have the cathode sloped portion 133a in the peripheral area of the first anode 131a or in the area overlapping the area in which the second sloped portion 131a2 of the first anode 131a is disposed.

As described above, since the cathode 133 has the cathode sloped portion 133a, light that would be reflected or totally reflected at the interface of the internal components of the display device 100 can be reflected by the cathode sloped portion 133a and extracted to the outside.

In addition, since the second anode 131b, a reflective electrode, is disposed in the anode open area 400 of the first anode 131a, as shown in FIG. 4, a portion of the light that would be reflected or totally reflected at the interface of the internal components of the display device 100 can be reflected by the second anode 131b and extracted to the outside. Accordingly, the light extraction efficiency of the display device 100 can be improved.

Here, when the light reflected by the second anode 131b travels in a direction parallel to the direction D1, for example, when the exit angle θₒᵤₜ of the reflected light is 0°, the light can be completely extracted to the outside of the display device 100 without being dissipated inside the display device 100, and the light extraction efficiency can be maximized.

Here, the exit angle θₒᵤₜ of the reflected light can be expressed by the following Equation 1:

$${θ}_{out} = 90 - ψ - {θ}_{PXL} \qquad [ Equation 1 ]$$

In Equation 1, θₒᵤₜ indicates an exit angle of light, θ_{PXL} indicates an inclination angle of the first sloped portion 131a1 of the first anode 131a, and ψ indicates an incident angle of light on the first anode 131a, emitted from the organic light-emitting layer (EML).

Referring to Equation 1, the equation θ_{PXL}=90−ψ must satisfied for the exit angle θₒᵤₜ of the reflected light to be 0°.

Here, as ψ varies, the intensity of the light emitted from the organic light-emitting layer (EML) and incident on the first anode 131a can vary.

In addition, even in a case in which light is incident from the organic light-emitting layer (EML) to the first anode 131a at the same ψ, i.e., at the same angle, the intensity of the light can vary depending on the type of the organic light-emitting layer (EML).

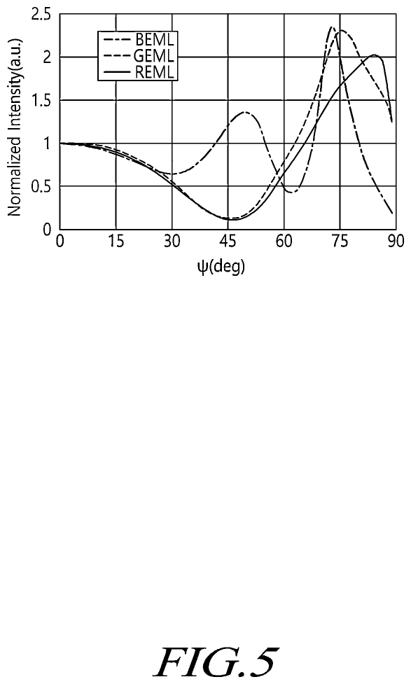

FIG. 5 illustrates the principle by which the light extraction efficiency of the display device according to exemplary embodiments of the present disclosure is improved.

The light-emitting layer 132 can include an organic light-emitting layer (EML) as described above, wherein the organic light-emitting layer (EML) can include a red organic light-emitting layer REML, a green organic light-emitting layer GEML, and a blue organic light-emitting layer BEML.

Taking the blue organic light-emitting layer BEML illustrated in FIG. 5 as an example, the intensity of light emitted from the blue organic light-emitting layer BEML and incident on the first anode 131a can vary as ψ varies. Referring to FIG. 5, it can be seen that the intensity of the light emitted from the blue organic light-emitting layer BEML and incident on the first anode 131a is maximized when ψ has a value of about 73°.

In other words, the intensity of the light emitted from the blue organic light-emitting layer BEML and incident on the first anode 131a is highest when the incident angle is about 73°. Therefore, the light extraction efficiency of the display device 100 can be most significantly improved when the light having an incident angle of 73° is extracted outward in a direction parallel to the direction D1, i.e., so that the exit angle θₒᵤₜ is 0°.

Referring to Equation 1, when ψ is 73°, θ_{PXL}, i.e., the inclination angle of the first sloped portion 131a1 of the first anode 131a, can be 17° for the exit angle θₒᵤₜ to be 0°.

In summary, as an example, in order to increase or maximize the light extraction efficiency of the light-emitting area of any subpixel SP in which the blue organic light-emitting layer BEML is disposed, the inclination angle of the first sloped portion 131a1 of the first anode 131a of the subpixel in which the blue organic light-emitting layer BEML is disposed can be set to about 17°.

Similarly, referring to FIG. 5, it can be seen that the intensity of light emitted from the red organic light-emitting layer REML and incident on the first anode 131a is maximized when ψ has a value of about 85°.

Referring to Equation 1, when ψ is 85°, in order for the exit angle θₒᵤₜ to be 0°, θ_{PXL}, i.e., the inclination angle of the first sloped portion 131a1 of the first anode 131a, can be about 5°.

Therefore, in order to increase or maximize the light extraction efficiency of the light-emitting area of any subpixel SP in which the red organic light-emitting layer REML is disposed, the inclination angle of the first sloped portion 131a1 of the first anode 131a of the subpixel in which the red organic light-emitting layer REML is disposed can be set to about 5°.

In addition, referring to FIG. 5, it can be seen that the intensity of light emitted from the green organic light-emitting layer GEML and incident on the first anode 131a is maximized when ψ has a value of about 77°.

Referring to Equation 1, when ψ is 77°, in order for the exit angle θₒᵤₜ to be 0°, θ_{PXL}, i.e., the inclination angle of the first sloped portion 131a1 of the first anode 131a, can be about 13°.

Therefore, in order to maximize the light extraction efficiency of the light-emitting area of any subpixel SP in which the green organic light-emitting layer GEML is disposed, the inclination angle of the first sloped portion 131a1 of the first anode 131a of the subpixel in which the green organic light-emitting layer GEML is disposed can be set about to 13°. It should be noted that the values of the above-mentioned angles are illustrated as an example, the present application is not limited thereto, and the values of the above-mentioned angles could be modified in various way.

As described above, in order to increase or maximize the light extraction efficiency of each of the subpixels SP in which the red organic light-emitting layer REML, the green organic light-emitting layer GEML, and the blue organic light-emitting layer BEML are disposed, the inclination angles θ_{PXL} of the first sloped portions 131a1 of the first anodes 131a included in the respective subpixels SP can be set differently. As an example, the respective first sloped portions 131a1 of the first anodes 131a can have different inclinations depending on the color of emitted light.

For example, the inclination angles of the first sloped portions 131a1 of the first anodes 131a included in the respective subpixels SP can be set differently depending on the type of light emitted from the respective subpixels SP so as to maximize the light extraction efficiencies of the respective subpixels SP.

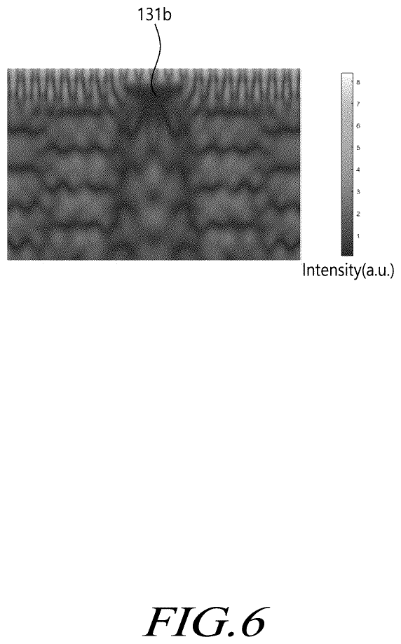

FIG. 6 illustrates an optical simulation image in a cross-sectional structure of the display device according to exemplary embodiments of the present disclosure.

The second anode 131b shown in FIG. 6 has a horizontal width of 2 μm, and the inclination angle θ_{PXL} of the first sloped portion 131a1 of the first anode 131a is 35°.

When the second anode 131b is disposed as in the example shown in FIG. 6, a portion of light emitted from the light-emitting layer 132 can be reflected by the second anode 131b to travel downwards. For example, it can be seen that a portion of light that would be reflected by the interface of the internal components of the display device 100 is reflected by the second anode 131b and proceeds downwards.

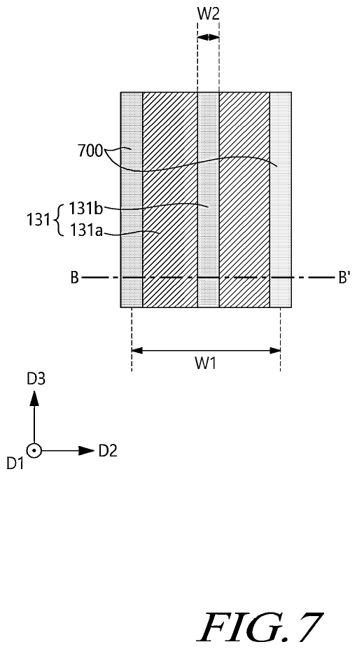

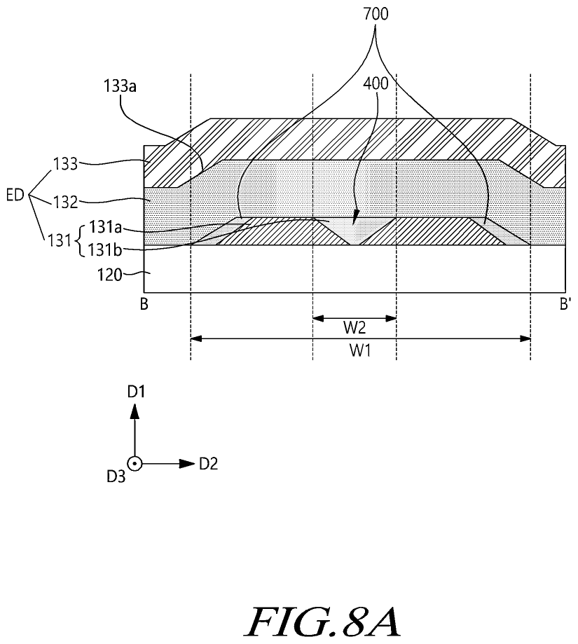

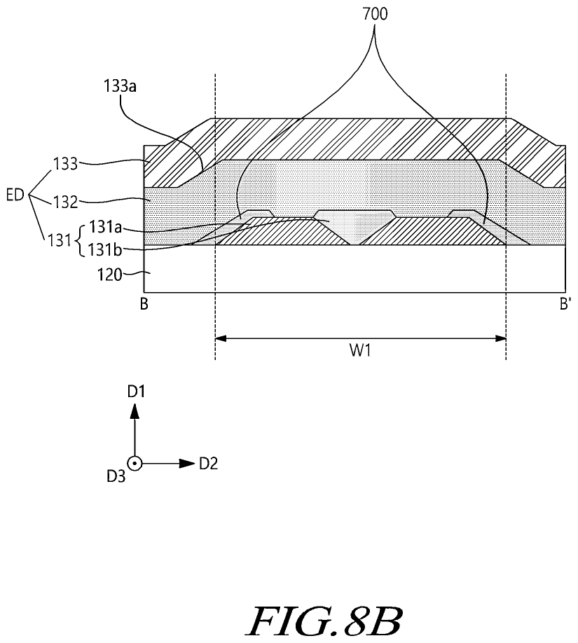

FIG. 7 illustrates another example planar structure of the display device according to embodiments of the present disclosure. FIGS. 8A and 8B illustrate an example cross-sectional structure of part along line B-B′ in FIG. 7.

In the following, a repeated description of those described above with reference to FIGS. 3 to 6 will be omitted or may be briefly provided.

Referring to FIG. 7, a second anode peripheral portion 700 can be further disposed in at least one of the peripheral areas of the first anode 131a.

The second anode peripheral portion 700 can be formed of the same material as the second anode 131b. For example, the second anode peripheral portion 700 can be formed of at least one of silver (Ag), aluminum (Al), gold (Au), molybdenum (Mo), tungsten (W), chromium (Cr), or alloys thereof. In addition, the second anode peripheral portion 700 can be formed together when the second anode 131b is formed. Embodiments are not limited thereto. As an example, the second anode peripheral portion 700 can be formed of a material different from the second anode 131b. As an example, the second anode peripheral portion 700 can be formed separately from the second anode 131b.

Referring to FIGS. 7 and 8A, the second anode peripheral portion 700 can be disposed over the first anode 131a and the overcoat layer 120.

The second anode peripheral portion 700 can have the same thickness as the first anode 131a and the second anode 131b in the direction D1. Embodiments are not limited thereto. As an example, the at least one of the first anode 131a, the second anode 131b and the second anode peripheral portion 700 can have a different thickness.

Since the second anode peripheral portion 700 has the same thickness as the first anode 131a and the second anode 131b, the light-emitting layer 132 can have a flat top surface in areas in which the first anode 131a and the second anode 131b are disposed.

The second anode peripheral portion 700 is disposed in the peripheral area of the first anode 131a, and thus can be disposed along the second sloped portion 131a2 of the first anode 131a.

Since the second anode peripheral portion 700 is disposed along the second sloped portion 131a2 of the first anode 131a, a portion of the light that would be totally reflected at the interface of the internal components of the display device 100 can be reflected by the second anode peripheral portion 700 and extracted to the outside.

For example, a portion of the light that would be totally reflected at the interface of the internal components of the display device 100 can be reflected by the second anode 131b and extracted to the outside, and another portion of the light can be reflected by the second anode peripheral portion 700 and extracted to the outside, thereby further improving the light extraction efficiency compared to a case in which only the second anode 131b is disposed.

In addition, the inclination angle of the second sloped portion 131a2 of the first anode 131a can be the same as the inclination angle θ_{PXL} of the first sloped portion 131a1 of the first anode 131a. As an example, the inclination angle of the first sloped portion 131a1 of the first anode 131a can be set so that light traveling in a direction parallel to the direction D1, i.e., light having an exit angle θₒᵤₜ of 0°, is intense or most intense. Therefore, according to Equation 1 above, the inclination angle of the second sloped portion 131a2 of the first anode 131a can be set so that light traveling in a direction parallel to the direction D1, i.e., light having an exit angle θₒᵤₜ of 0°, is intense or most intense. As a result, the light extraction efficiency can be increased or maximized.

Referring to the example described above, light incident on the first anode 131a from the blue organic light-emitting layer BEML is most intense when the incident angle is 77°, and thus light extraction efficiency can be increased or maximized when light having an incident angle of 77° is extracted in a direction parallel to the direction D1.

Therefore, with reference to Equation 1, when the inclination angle of the second sloped portion 131a2 of the first anode 131a of the subpixel SP in which the blue organic light-emitting layer BEML is disposed is set to 13°, which is the same as the inclination angle θ_{PXL} of the first sloped portion 131a1 of the first anode 131a, the light extraction efficiency of light traveling in a direction parallel to the direction D1 can be increased or maximized.

For example, the inclination angles of the second sloped portions 131a2 of the first anodes 131a included in the respective subpixels SP can be set differently depending on the type of light emitted from the respective subpixels SP so as to increase or maximize the light extraction efficiencies of the respective subpixels SP.

Referring to FIG. 8B, the thickness of at least one of the second anode 131b and the second anode peripheral portion 700 in the direction D1 can be greater than the thickness of the first anode 131a. For example, the height of the top surface of each of the second anode 131b and the second anode peripheral portion 700 can be higher than the height of the top surface of the first anode 131a.

As an example, the thickness of the second anode 131b and the thickness of the second anode peripheral portion 700 can be the same. Embodiments are not limited thereto. As an example, the thickness of the second anode 131b and the thickness of the second anode peripheral portion 700 can be different from each other.

Since the top surface of each of the second anode 131b and the second anode peripheral portion 700 is higher than the top surface of the first anode 131a, the second anode 131b and the second anode peripheral portion 700 can cover portions of the top surface of the first anode 131a.

Since the light-emitting layer 132 is formed along the step portion of the substructure, the light-emitting layer 132 can have a partially convex shape in an area in which the second anode 131b and the second anode peripheral portion 700 are disposed.

In addition, the light-emitting layer 132 can have a sloped surface, the angle of which is the same as the inclination angle of an outer portion of the second anode peripheral portion 700, in an area overlapping an area in which the second anode peripheral portion 700 is disposed.

Similarly, the cathode 133 can have a partially convex shape in the area overlapping the areas in which the second anode 131b and the second anode peripheral portion 700 are disposed.

In addition, the cathode 133 can have a cathode sloped portion 133a, the angle of which is the same as the inclination angle of the outer portion of the second anode peripheral portion 700, in the area overlapping the area in which the second anode peripheral portion 700 is disposed.

Since the light-emitting layer 132 has a convex shape in the area overlapping the area in which the second anode peripheral portion 700 is disposed, the length of the cathode sloped portion 133a can be longer than that in the case in which the second anode peripheral portion 700 has the same thickness as the first anode 131a in the direction D1.

For example, increasing the length of the cathode sloped portion 133a can increase the area from which light that would be totally reflected at the interface of the internal components of the display device 100 can be reflected, thereby further improving the light extraction efficiency of the display device 100.

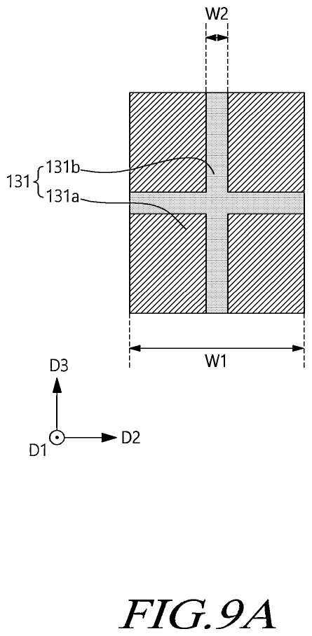

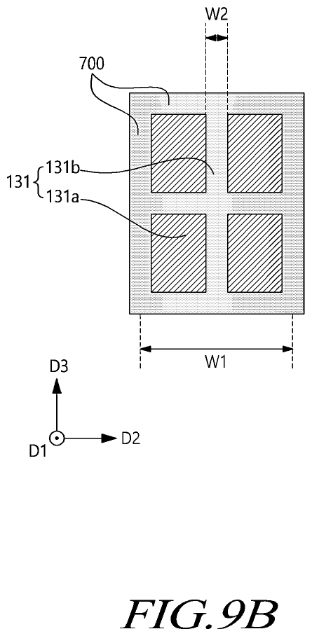

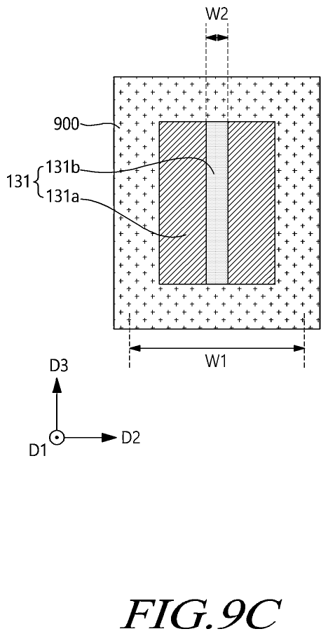

FIGS. 9A to 9C illustrate various example planar structures of the display device according to embodiments of the present disclosure.

Referring to FIG. 9A, the second anode 131b can be disposed to extend not only in a direction parallel to the direction D3 but also in a direction parallel to the direction D2.

The first anode 131a can further include an anode open area extending in the direction parallel to the direction D2. The second anode 131b can be further disposed in the anode open area extending in the direction parallel to the direction D2.

Since the first anode 131a further includes the anode open area extending in the direction parallel to the direction D2 in addition to the anode open area 400 extending in the direction parallel to the direction D3 and the second anode 131b is further disposed in the anode open area extending in the direction parallel to the direction D2, a greater portion of light that would be totally reflected at the interface of the internal components of the display device 100 can be extracted to the outside, thereby improving the light extraction efficiency of the display device 100.

For example, in light that would be totally reflected at the interface of the internal components of the display device 100, a portion of light traveling in the direction parallel to the direction D2 is reflected by the second anode 131b disposed in the anode open area 400 extending in the direction parallel to the direction D3 so as to be extracted to the outside and a portion of light traveling in the direction parallel to the direction D3 is reflected by the second anode 131b disposed in the anode open area 400 extending in the direction parallel to the direction D2 so as to be extracted to the outside. As a result, a higher light extraction efficiency can be obtained than in the case described above with reference to FIG. 3.

Referring to FIG. 9B, the second anode peripheral portion 700 can be disposed not only in the peripheral areas of the first anode 131a extending in the direction parallel to the direction D2, but also in the peripheral areas of the first anode 131a extending in the direction parallel to direction D3.

Accordingly, in light totally reflected at the interface of the internal components of the display device 100, a portion of light traveling in the direction parallel to the direction D2 is reflected by the second anode peripheral portion 700 in the peripheral area of the first anode 131a extending in the direction parallel to the direction D2 so as to be extracted to the outside, and a portion of light traveling in the direction parallel to direction D3 is reflected by the second anode peripheral portion 700 in the peripheral area of the first anode 131a extending in the direction parallel to direction D3 so as to be extracted to the outside. As a result, a higher light extraction efficiency can be obtained than in the case described above with reference to FIG. 7.

Referring to FIG. 9C, a bank layer 900 can further be disposed, for example, around the first anode 131a.

As an example, the bank layer 900 can be disposed to cover a portion of the first anode 131a and the second anode 131b.

Since the bank layer 900 covers outer peripheral portions of the first anode 131a, the light-emitting layer 132 can be deposited without interruption even in a case in which the first anode 131a is deposited over the overcoat layer 120 without the above-described surface treatment, thereby reducing or preventing the limitation of poor lighting that can occur because the light-emitting layer 132 is not properly deposited.

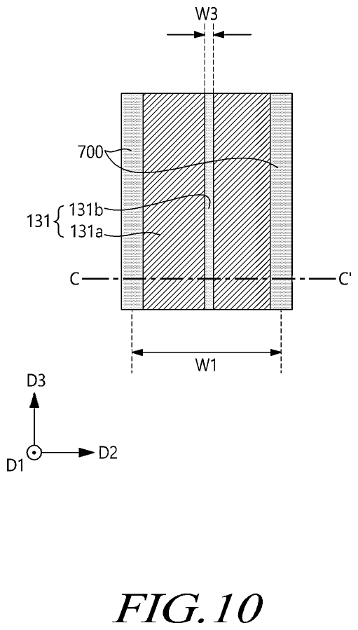

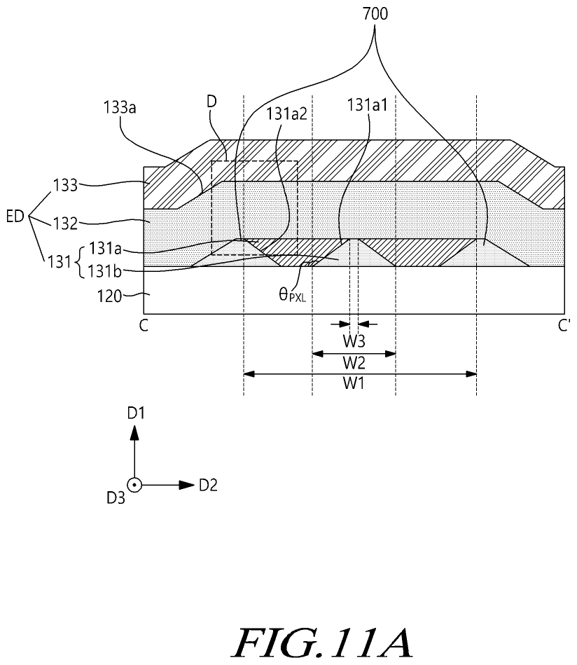

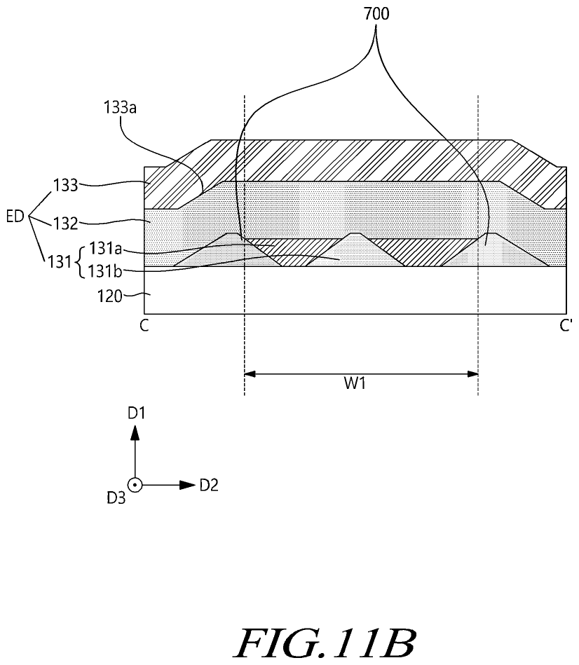

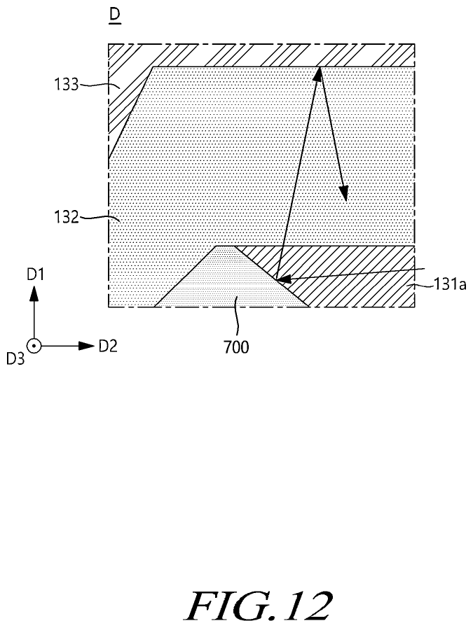

FIG. 10 illustrates another example planar structure of the display device according to embodiments of the present disclosure. FIGS. 11A and 11B illustrate example cross-sectional structures of part along line C-C′ in FIG. 10. FIG. 12 is an enlarged view of part D in FIG. 11A.

Referring to FIGS. 10 and 11A, first, the second anode 131b can be formed on the overcoat layer 120.

Since the second anode 131b has good adhesion with the overcoat layer 120, the second anode 131b can be formed to have an inclination angle between 0° and 90° with respect to the overcoat layer 120, even in a case in which the overcoat layer 120 is not subjected to a special surface treatment, such as plasma treatment. For example, the second anode 131b can have a trapezoidal shape as shown in FIG. 11A.

The width of the bottom surface of the second anode 131b can be W2 and the width of the top surface can be W3. Here, W3 can be smaller than W2.

After the second anode 131b is formed first, the first anode 131a can be provided on both peripheral areas of the second anode 131b.

At this time, since the second anode 131b has the inclination angle between 0° and 90° with the overcoat layer 120, the first anode 131a can be provided on the peripheral portions of the second anode 131b so that first sloped portions 131a1 and second sloped portions 131a2 of the first anode 131a have an inclination angle θ_{PXL} of 90° or greater.

In the outermost areas of the first anode 131a, i.e., the peripheral areas of the second sloped portions 131a2 of the first anode 131a, a second anode peripheral portion 700 can be further provided.

Since the inclination angle θ_{PXL} of the second sloped portions 131a2 of the first anode 131a is 90° or greater, the second anode peripheral portion 700 can be formed to have an inclination angle between 0° and 90° with respect to the overcoat layer 120 like the second anode 131b.

As the second anode peripheral portion 700 is provided, the light-emitting layer 132 can have sloped surfaces in areas overlapping the areas in which the second anode peripheral portion 700 is provided, as described above. Similarly, the cathode 133 can have cathode sloped portions 133a in areas overlapping the areas in which the second anode peripheral portion 700 is provided.

Since the cathode 133 has the cathode sloped portions 133a as described above, light that would be totally reflected at the interface of the internal components of the display device 100 can be reflected by the cathode sloped portions 133a so as to be extracted to the outside.

In addition, a portion of the light that would be totally reflected at the interface of the internal components of the display device 100 can be reflected by the second anode 131b or the second anode peripheral portion 700 and thus extracted to the outside.

FIG. 12 is an enlarged view of part D in FIG. 11A.

Referring to FIG. 12, a portion of light that would be totally reflected at the interface of the internal components of the display device 100 can pass through the first anode 131a so as to be reflected by the second anode peripheral portion 700.

Since the inclination angle of the second anode peripheral portion 700 is between 0° and 90° with respect to the overcoat layer 120, light reflected by the second anode peripheral portion 700 can travel toward the upper part of the display device 100, i.e., in the direction D1. The light that has traveled in the direction D1 can be reflected back by the cathode 133. The light reflected back by the cathode 133 can also travel toward the lower part of the display device 100 and be extracted to the outside of the display device 100.

A portion of the light that would be totally reflected at the interface of the internal components of the display device 100 can also pass through the first anode 131a and be reflected by the second anode 131b.

Since the inclination angle of second anode 131b is between 0° and 90° with respect to the overcoat layer 120, the light reflected by the second anode 131b can travel in the direction D1 and be reflected back by the cathode 133. Furthermore, the light reflected back by the cathode 133 can travel toward the lower part of the display device 100 and be extracted to the outside of the display device 100.

For example, even in a case in which the first sloped portion 131a1 and the second sloped portion 131a2 of the first anode 131a are arranged to have an inclination angle θ_{PXL} of 90° or more, the light extraction efficiency of the display device 100 can be improved by the second anode 131b or the second anode peripheral portion 700 arranged on the periphery of the first anode 131a. As an example, one of the second anode 131b and the second anode peripheral portion 700 can be omitted depending on the design.

Referring to FIG. 11B, the thickness of each of the second anode 131b and the second anode peripheral portion 700 can be greater than the thickness of the first anode 131a.

For example, the height of the top surface of at least one or each of the second anode 131b and the second anode peripheral portion 700 can be higher than the height of the top surface of the first anode 131a.

As an example, the thicknesses of the second anode 131b and the second anode peripheral portion 700 in the direction D1 can be the same, or can be different from each other.

Since the top surface of each of the second anode 131b and the second anode peripheral portion 700 is higher than the top surface of the first anode 131a, the second anode 131b and the second anode peripheral portion 700 can cover portions of the top surface of the first anode 131a.

In this case, the light-emitting layer 132 is formed along a step portion of the substructure, and thus the light-emitting layer 132 can have a partially convex shape in an area in which the second anode 131b and the second anode peripheral portion 700 are provided.

In addition, the light-emitting layer 132 can have sloped surfaces, the angle of which is the same as the inclination angle of the outer portion of the second anode peripheral portion 700, in areas overlapping the areas in which the second anode peripheral portion 700 are provided.

In addition, the cathode 133 can have cathode sloped portions 133a, the angle of which is the same as the inclination angle of the outer portion of the second anode peripheral portion 700, in areas overlapping the areas in which the second anode peripheral portion 700 is provided.

In this case, the light-emitting layer 132 has a convex shape in the area overlapping the areas in which the second anode peripheral portion 700 is provided, and thus the length of each of the cathode sloped portions 133a can be longer than in the case in which the second anode peripheral portion 700 has the same thickness as the first anode 131a in the direction D1.

For example, increasing the length of the cathode sloped portion 133a can increase the area from which light that would be totally reflected at the interface of the internal components of the display device 100 can be reflected, thereby further improving the light extraction efficiency of the display device 100.

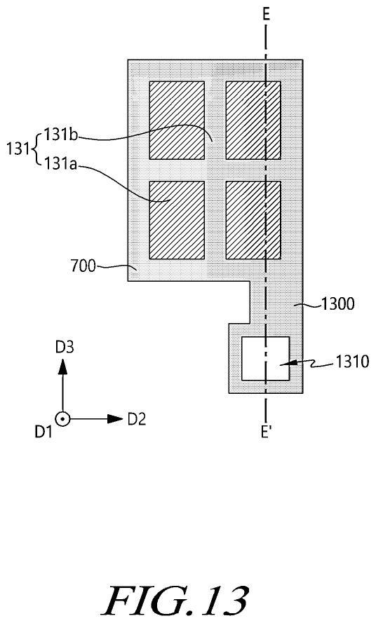

FIG. 13 illustrates an example planar structure including a circuit connector in the display device according to embodiments of the present disclosure.

Referring to FIG. 13, the first anode 131a can extend in a direction parallel to the direction D3.

The second anode peripheral portion 700 can be disposed in at least one or all of the peripheral areas of the first anode 131a extending in the direction parallel to direction D3.

A second anode connector 1300 can be further disposed in a peripheral portion of the second anode peripheral portion 700.

Referring to FIG. 13, the second anode connector 1300 can extend to a contact hole 1310 for connecting the driving transistor T1 and the light-emitting element ED.

The second anode connector 1300 can be connected to the driving transistor T1 through contact hole 1310.

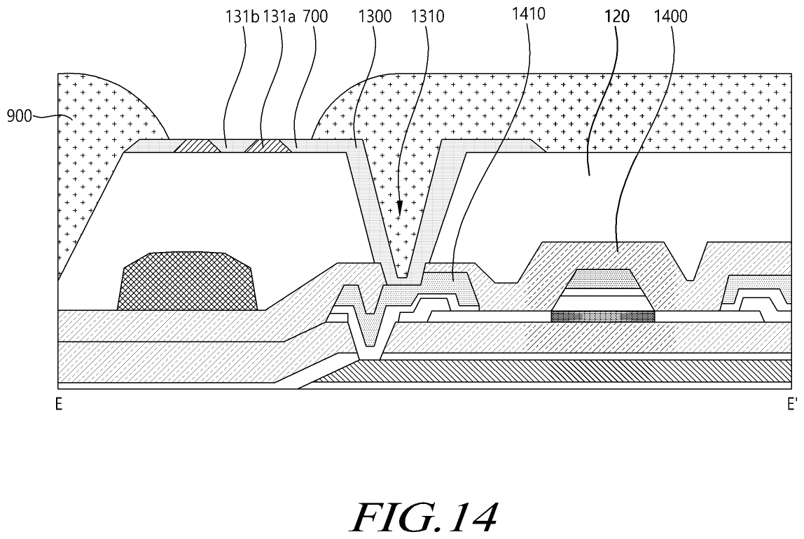

FIG. 14 illustrates an example cross-sectional structure of part along line E-E′ in FIG. 13.

Referring to FIG. 14, the overcoat layer 120 and an interlayer insulating layer 1400 can be open in the area in which the contact hole 1310 is disposed.

The second anode connector 1300 can be disposed in the area in which the overcoat layer 120 and the interlayer insulating layer 1400 are open. The second anode connector 1300 can be disposed to cover sidewalls of the opened overcoat layer 120 and the interlayer insulating layer 1400 or open areas of the overcoat layer 120 and the interlayer insulating layer 1400, and can be electrically connected to a drain electrode 1410 of the driving transistor T1.

In this case, the first anode 131a can be located in a light-emitting area defined by the open area of the bank layer 900. Although a case in which the inclination angle θ_{PXL} of the first anode 131a is between 0° and 90° is shown only in FIG. 14, the present disclosure is not limited thereto, and the inclination angle θ_{PXL} of the first anode 131a can be greater than 90°.

As shown in FIG. 14, the second anode connector 1300 can be formed of the same material as the second anode 131b and the second anode peripheral portion 700, without being limited thereto. As an example, the second anode connector 1300 can be formed of a different material from that of the second anode 131b and the second anode peripheral portion 700. As an example, the second anode connector 1300 can be implemented using an opaque conductive material reflecting light, and can be formed from at least one of, for example, silver (Ag), aluminum (Al), gold (Au), molybdenum (Mo), tungsten (W), chromium (Cr), or alloys thereof, without being limited thereto.

The use of a low resistance metal material in the second anode connector 1300, i.e., an electrode for connecting the driving transistor T1 and the light-emitting element ED, can advantageously lower the sheet resistance or the contact resistance compared to the case in which the same material as in the first anode 131a, i.e., a material such as indium tin oxide (ITO) and indium zinc oxide (IZO), is used.

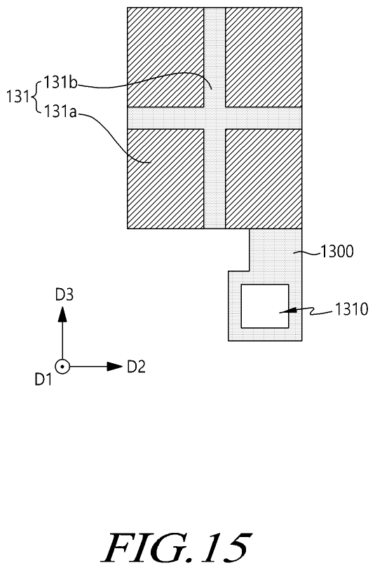

FIG. 15 illustrates another example planar structure including a circuit connector in the display device according to embodiments of the present disclosure.

Referring to FIG. 15, the second anode peripheral portion 700 may not be disposed in a peripheral area of the first anode 131a.

Since the second anode peripheral portion 700 is not disposed in the peripheral area of the first anode 131a, the first anode 131a can directly abut the second anode connector 1300 and be electrically connected to the second anode connector 1300.

In a case in which the second anode peripheral portion 700 is not disposed in the peripheral area of the first anode 131a, the first anode 131a can have a larger area in a direction parallel to the direction D3. When the first anode 131a has a larger area, light emitted from the light-emitting layer 132 can pass through the larger area to be extracted to the outside, thereby improving the light extraction efficiency of the display device 100.

The embodiments of the present disclosure described above are briefly reviewed as follows.

Embodiments of the present disclosure can provide a display device including: an overcoat layer over a substrate; a first anode disposed over the overcoat layer and including at least one anode open area; a second anode disposed over the same layer as the first anode, with a portion thereof being disposed in the anode open area; a light-emitting layer disposed over the first anode and the second anode; and a cathode disposed over the light-emitting layer.

In the display device according to embodiments of the present disclosure, the first anode can be a transmitting electrode, and a second anode can be a reflecting electrode.

In the display device according to embodiments of the present disclosure, the first anode and the second anode can have the same thickness.

In the display device according to embodiments of the present disclosure, the first anode can include a first sloped portion in an area in which the anode open area is disposed and a second sloped portion in a peripheral area. Each of the first sloped portion and the second sloped portion the first anode can have an inclination of 90° or less.

In the display device according to embodiments of the present disclosure, the cathode can include a cathode sloped portion in an area overlapping the second sloped portion of the first anode.

In the display device according to embodiments of the present disclosure, the light-emitting layer can include a flat top surface between the cathode sloped portions.

In the display device according to embodiments of the present disclosure, the light-emitting layer can include a red light-emitting layer, a green light-emitting layer, and a blue light-emitting layer. The first sloped portions of the first anodes included in an area in which the red light-emitting layer is disposed, an area in which the green light-emitting layer is disposed, and an area in which the blue light-emitting layer is disposed can have different inclinations.

In the display device according to embodiments of the present disclosure, the second anode disposed in the anode open area can have a horizontal width of 700 nm or more.

The display device according to embodiments of the present disclosure can further include a second anode peripheral portion disposed over the first anode and the overcoat layer in a peripheral portion of the first anode.

In the display device according to embodiments of the present disclosure, the thickness of the second anode can be greater than the thickness of the first anode.

In the display device according to embodiments of the present disclosure, the first anode can include a first sloped portion in an area in which the anode open area is provided and a second sloped portion in a peripheral area. Each of the first sloped portion and the second sloped portion the first anode can have an inclination of 90° or less.

The display device according to embodiments of the present disclosure can further include a bank layer disposed over the overcoat layer and the first anode and having a bank open area.

Embodiments of the present disclosure can provide a display device including: an overcoat layer over a substrate; a plurality of first anodes disposed over the overcoat layer to be spaced apart from each other; a plurality of second anodes disposed over the same layer as the first anodes such that the second anodes are spaced apart from each other, the second anodes alternating with the first anodes while filling between the first anodes; a light-emitting layer disposed over the first anodes and the second anodes; and a cathode disposed over the light-emitting layer.

In the display device according to embodiments of the present disclosure, the first anodes and the second anodes can have the same thickness.

In the display device according to embodiments of the present disclosure, the cathode can include a cathode sloped portion in an area overlapping an outermost area of the first anodes or the second anodes.

In the display device according to embodiments of the present disclosure, the light-emitting layer can include a flat top surface between the cathode sloped portions.

In the display device according to embodiments of the present disclosure, the thickness of each of the second anodes can be greater than the thickness of each of the first anodes.

Embodiments of the present disclosure can provide a display device including: a transistor on a substrate; an overcoat layer disposed over the transistor and having an open area; a first anode disposed over the overcoat layer and including at least one anode open area; a second anode disposed over the same layer as the first anode, with at least a portion thereof being disposed in the anode open area; and a second anode connector horizontally extending from a peripheral portion of the first anode and disposed to cover the open area.

The display device according to embodiments of the present disclosure can further include a second anode peripheral portion disposed between the first anode and the second anode connector.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present disclosure. The above description and the accompanying drawings provide an example of the technical idea of the present disclosure for illustrative purposes only. For example, the disclosed embodiments are intended to illustrate the scope of the technical idea of the present disclosure.

What is claimed is:

1. A display device comprising:
an overcoat layer disposed over a substrate;
a first anode disposed over the overcoat layer and comprising an anode open area;
a second anode disposed over a same layer as the first anode, with a portion of the second anode being disposed in the anode open area;
a light-emitting layer disposed over the first anode and the second anode; and
a cathode disposed over the light-emitting layer.

2. The display device of claim 1, wherein the first anode is a transmitting electrode, and the second anode is a reflecting electrode.

3. The display device of claim 1, wherein the first anode and the second anode have a same thickness.

4. The display device of claim 1, wherein the first anode comprises a first sloped portion overlapping with the second anode and having an inclination of less than 90° or greater than 90°.

5. The display device of claim 1, wherein the first anode comprises a first sloped portion in an area in which the anode open area is disposed and a second sloped portion in a peripheral area, and
each of the first sloped portion and the second sloped portion of the first anode has an inclination of 90° or less.

6. The display device of claim 5, wherein the cathode comprises a cathode sloped portion in an area overlapping the second sloped portion of the first anode.

7. The display device of claim 6, wherein the light-emitting layer comprises a flat top surface disposed between cathode sloped portions.

8. The display device of claim 5, wherein the first sloped portion and the second sloped portion of the first anode have the same inclination.

9. The display device of claim 5, wherein the light-emitting layer comprises a red light-emitting layer, a green light-emitting layer, and a blue light-emitting layer,
the first sloped portions of the first anodes included in an area in which the red light-emitting layer is disposed, an area in which the green light-emitting layer is disposed, and an area in which the blue light-emitting layer is disposed, have different inclinations.

10. The display device of claim 9, wherein the inclination of the first sloped portions of the first anodes included in an area in which the red light-emitting layer is disposed is smaller than the inclination of the first sloped portions of the first anodes included in an area in which the green light-emitting layer is disposed, and
wherein the inclination of the first sloped portions of the first anodes included in an area in which the green light-emitting layer is disposed is smaller than the inclination of the first sloped portions of the first anodes included in an area in which the blue light-emitting layer is disposed.

11. The display device of claim 9, wherein the inclination of the first sloped portions of the first anodes included in an area in which the red light-emitting layer is disposed is about 5°,
the inclination of the first sloped portions of the first anodes included in an area in which the green light-emitting layer is disposed is about 13°, and
the inclination of the first sloped portions of the first anodes included in an area in which the blue light-emitting layer is disposed is about 17°.

12. The display device of claim 5, wherein the inclination of the first sloped portion of the first anode is set so that a light having an exit angle of 0° is a light most intense as an incident angle of light on the first anode varies.

13. The display device of claim 1, wherein the second anode disposed in the anode open area has a horizontal width of about 700 nm or more.

14. The display device of claim 1, further comprising a second anode peripheral portion disposed over the first anode and the overcoat layer in a peripheral portion of the first anode.

15. The display device of claim 14, wherein a thickness of the second anode is greater than a thickness of the first anode.

16. The display device of claim 14, wherein the thickness of the second anode and the second anode peripheral portion is greater than the thickness of the first anode, and
the cathode has a partially convex shape in an area in which the second anode and the second anode peripheral portion are disposed.

17. The display device of claim 14, wherein the first anode comprises a first sloped portion in an area in which the anode open area is provided and a second sloped portion in a peripheral area, and
each of the first sloped portion and the second sloped portion of the first anode has an inclination of 90° or more.

18. The display device of claim 1, wherein the anode open area has an inverted trapezoidal shape, and penetrates the first anode to expose the overcoat layer.

19. The display device of claim 1, further comprising a bank layer disposed over the overcoat layer and the first anode, and having a bank open area.

20. A display device comprising:
an overcoat layer over a substrate;
a plurality of first anodes disposed over the overcoat layer to be spaced apart from each other;
a plurality of second anodes disposed over a same layer as the first anodes so that the second anodes are spaced apart from each other, the second anodes alternating with the first anodes while filling between the first anodes;
a light-emitting layer disposed over the first anodes and the second anodes; and
a cathode disposed over the light-emitting layer.

21. The display device of claim 20, wherein the first anodes and the second anodes have a same thickness.

22. The display device of claim 20, wherein the cathode comprises a cathode sloped portion in an area overlapping an outermost area of the first anodes or the second anodes.

23. The display device of claim 22, wherein the light-emitting layer comprises a flat top surface disposed between the cathode sloped portions.

24. The display device of claim 20, wherein a thickness of each of the second anodes is greater than a thickness of each of the first anodes.

25. A display device comprising:
a transistor disposed over a substrate;
an overcoat layer disposed over the transistor and having an open area;
a first anode disposed over the overcoat layer and comprising at least one anode open area;
a second anode disposed over a same layer as the first anode, with at least a portion thereof being disposed in the at least one anode open area; and
a second anode connector horizontally extending from a peripheral portion of the first anode and disposed to cover the open area.

26. The display device of claim 25, further comprising a second anode peripheral portion disposed between the first anode and the second anode connector.
